(19) United States
(12) Patent Application Publication
(10) Pub. No.: US 2025/0364241 A1
(43) Pub. Date: Nov. 27, 2025

(54) WAFER PROCESSING METHOD, INGOT PROCESSING METHOD, AND WAFER

(71) Applicant: DISCO CORPORATION, Tokyo (JP)

(72) Inventor: Kazuma SEKIYA, Tokyo (JP)

(21) Appl. No.: 19/198,768

(22) Filed: May 5, 2025

(30) Foreign Application Priority Data
May 21, 2024 (JP) 2024-082703

(51) Int. Cl. H01L 21/02; H10D 62/40

(52) U.S. Cl. CPC H01L 21/02027; H10D 62/405

(57) ABSTRACT

A wafer processing method for a wafer formed of a semiconductor material includes: preparing a wafer that includes a front surface, a back surface on a rear surface of the front surface, and a side surface ranging from the front surface to the back surface and includes a flat mirror surface portion indicating a crystal orientation of the wafer on the side surface; and grinding the back surface of the wafer prepared in the preparing to form a recess and form a projection surrounding the recess.

### CROSS-REFERENCE TO RELATED APPLICATION(S)

The present application claims priority to and incorporates by reference the entire contents of Japanese Patent Application No. 2024-082703 filed in Japan on May 21, 2024.

### TECHNICAL FIELD

The present disclosure relates to a wafer processing method, an ingot processing method, and a wafer.

### BACKGROUND

On a wafer formed of a semiconductor material, a notch or an orientation flat is formed at an outer periphery of the wafer as a mark indicating a crystal orientation of the wafer.

Meanwhile, to facilitate handling after grinding and thinning the wafer, a technique of forming a recess by grinding a central region of the wafer and forming a projection by maintaining a thickness at an outer periphery of the wafer such that the projection functions as a reinforcement has been widely adopted in the market (for example, JP 2010-245172 A).

However, when a notch is formed on the wafer, a width of the projection needs to be set to be equal to or larger than a width of the notch or more for the projection to function as a reinforcement, and there is a demand for forming a recess having a larger area, in order to form a larger number of devices.

### SUMMARY

A wafer processing method according to one aspect of the present disclosure is for processing a wafer formed of a semiconductor material. The wafer processing method includes: preparing a wafer that includes a front surface, a back surface on a rear surface of the front surface, and a side surface ranging from the front surface to the back surface and includes a flat mirror surface portion indicating a crystal orientation of the wafer on the side surface; and grinding the back surface of the wafer prepared in the preparing to form a recess and form a projection surrounding the recess.

An ingot processing method according to another aspect of the present disclosure is for processing an ingot formed of a semiconductor material. The ingot processing method includes: detecting a crystal orientation of the ingot; forming a linear flat mirror surface portion along an extending direction of the ingot based on the crystal orientation detected in the detecting; separating a part of the ingot to form a wafer after the forming; and grinding a back surface of the wafer to form a recess and form a projection surrounding the recess.

A wafer according to still another aspect of the present disclosure includes a front surface, a back surface on a rear surface of the front surface, and a side surface ranging from the front surface to the back surface and includes a flat mirror surface portion indicating a crystal orientation of the wafer.

### BRIEF DESCRIPTION OF THE DRAWINGS

FIG. 1 is a perspective view schematically illustrating an ingot to be processed in an ingot processing method according to a first embodiment;

FIG. 2 is a flowchart illustrating a flow of the ingot processing method according to the first embodiment;

FIG. 3 is a perspective view schematically

illustrating a configuration example of a laser processing device used in a wafer forming step of the ingot processing method illustrated in FIG. 2;

FIG. 4 is a diagram illustrating a configuration example of a laser beam irradiation unit of the laser processing device illustrated in FIG. 3;

FIG. 5 is a cross-sectional view schematically illustrating a state where an ingot is irradiated with a laser beam in the wafer forming step of the ingot processing method illustrated in FIG. 2;

FIG. 6 is a cross-sectional view schematically illustrating adjacent separation layers formed inside the ingot illustrated in FIG. 5;

FIG. 7 is a side view schematically illustrating an orientation detection step of the ingot processing method illustrated in FIG. 2;

FIG. 8 is a side view schematically illustrating a linear flat mirror surface portion forming step of the ingot processing method illustrated in FIG. 2;

FIG. 9 is a side view schematically illustrating a modification example of the linear flat mirror surface portion forming step of the ingot processing method illustrated in FIG. 8;

FIG. 10 is a plan view schematically illustrating a crystal orientation of a wafer where a linear flat mirror surface portion is formed in the linear flat mirror surface portion forming step of the ingot processing method illustrated in FIG. 2;

FIG. 11 is a perspective view schematically illustrating a crystal orientation of a wafer on which devices are formed in the linear flat mirror surface portion forming step of the ingot processing method illustrated in FIG. 2;

FIG. 12 is a side view illustrating a portion XII in FIG. 11;

FIG. 13 is a cross-sectional view of the wafer taken along a line XIII-XIII in FIG. 11;

FIG. 14 is a cross-sectional view illustrating a modification example of the wafer illustrated in FIG. 13;

FIG. 15 is a perspective view schematically illustrating a configuration example of a grinding device used in a grinding step and the like of the ingot processing method illustrated in FIG. 2;

FIG. 16 is a side view schematically illustrating a configuration of a detection unit of the grinding device illustrated in FIG. 15;

FIG. 17 is a cross-sectional view schematically illustrating a state where a holding table of the grinding device holds the wafer in the grinding step of the ingot processing method illustrated in FIG. 2;

FIG. 18 is a cross-sectional view schematically illustrating a state where a grinding unit of the grinding device grinds the wafer in the grinding step of the ingot processing method illustrated in FIG. 2;

FIG. 19 is a front view schematically illustrating a wafer cassette in which the wafer is stored in a storage step of the ingot processing method illustrated in FIG. 2;

FIG. 20 is a flowchart illustrating a flow of an ingot processing method according to a second embodiment;

FIG. 21 is a side view schematically illustrating an orientation detection step of the ingot processing method illustrated in FIG. 20;

FIG. 22 is a side view schematically illustrating a linear flat mirror surface portion forming step of the ingot processing method illustrated in FIG. 20;

FIG. 23 is a side view schematically illustrating a modification example of the linear flat mirror surface portion forming step of the ingot processing method illustrated in FIG. 20;

FIG. 24 is a side view schematically illustrating another modification example of the linear flat mirror surface portion forming step of the ingot processing method illustrated in FIG. 20;

FIG. 25 is a perspective view schematically illustrating an ingot after the linear flat mirror surface portion forming step of the ingot processing method illustrated in FIG. 20; and

FIG. 26 is a plan view schematically illustrating a crystal orientation of an ingot on which a linear flat mirror surface portion is formed in the linear flat mirror surface portion forming step of the ingot processing method illustrated in FIG. 20.

### DETAILED DESCRIPTION

Embodiments of the present disclosure will be described in detail with reference to the drawings. The present invention is not limited to the contents described in the following embodiments. Components described below include components that are easily conceivable by those skilled in the art and components that are substantially the same. Configurations described below can be appropriately combined. Within a range not departing from the scope of the present invention, various omissions, substitutions, or modifications can be made for the configurations.

### First Embodiment

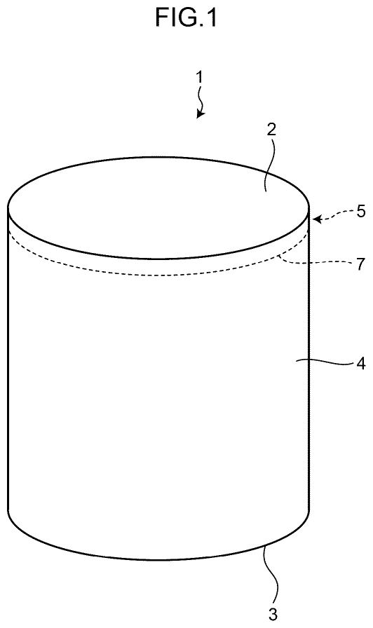

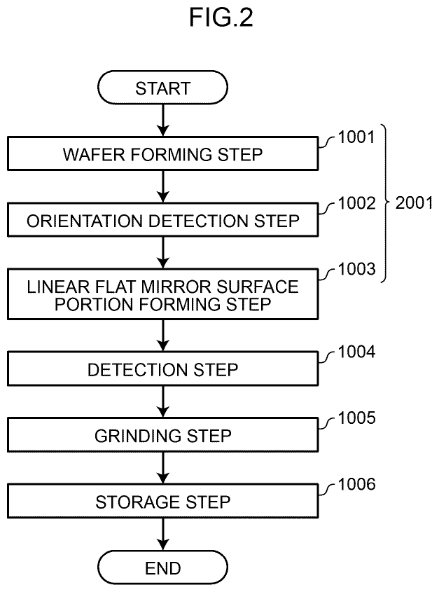

An ingot processing method according to a first embodiment of the present invention will be described based on the drawings. FIG. 1 is a perspective view schematically illustrating an ingot to be processed in the ingot processing method according to the first embodiment. FIG. 2 is a flowchart illustrating a flow of the ingot processing method according to the first embodiment.

### Ingot

The ingot processing method according to the first embodiment is a method of processing an ingot 1 illustrated in FIG. 1. The ingot 1 to be processed in the ingot processing method according to the first embodiment is formed of silicon in the first embodiment, and is formed in a cylindrical shape as a whole as illustrated in FIG. 1. In the first embodiment, the ingot 1 is formed of single crystal silicon that is a semiconductor material. In the present invention, the semiconductor material forming the ingot 1 is not limited to silicon.

As illustrated in FIG. 1, the ingot 1 includes a circular first surface 2 that is an end surface, a circular second surface 3 that is on the back surface side of the first surface 2, and an outer peripheral surface 4 continuous with an outer edge of the first surface 2 and an outer edge of the second surface 3. The ingot 1 is formed in a mirror-finished surface by grinding and polishing at least the first surface 2. In the ingot 1 before performing the ingot processing method according to the first embodiment, a mark indicating a crystal orientation is not formed. In the first embodiment, the first surface 2 is the (100) plane of the ingot 1.

As illustrated in FIG. 2, the ingot processing method according to the first embodiment includes a wafer forming step 1001, an orientation detection step 1002, a linear flat mirror surface portion forming step 1003, a detection step 1004, a grinding step 1005, and a storage step 1006.

### Wafer Forming Step

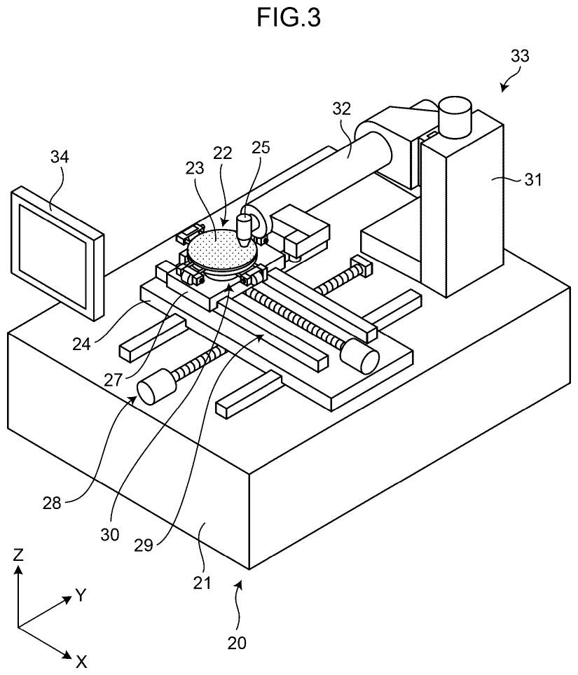

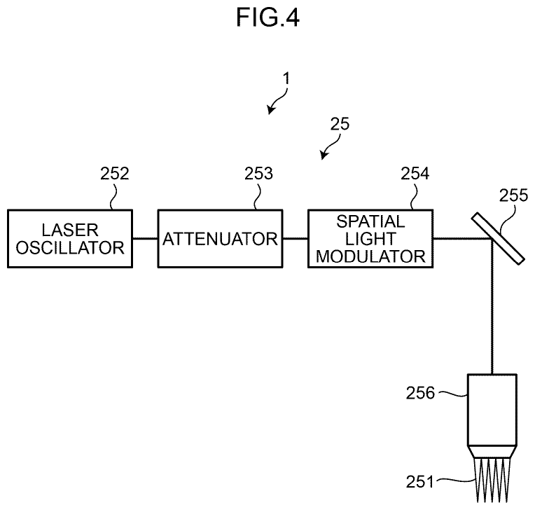

FIG. 3 is a perspective view schematically illustrating a configuration example of a laser processing device used in the wafer forming step of the ingot processing method illustrated in FIG. 2. FIG. 4 is a diagram illustrating a configuration example of a laser beam irradiation unit of the laser processing device illustrated in FIG. 3. In the wafer forming step 1001, the laser processing device illustrated in FIG. 3 is used.

### Laser Processing Device

First, a laser processing device 20 will be described. As illustrated in FIG. 3, the laser processing device 20 includes a holding table 22, a laser beam irradiation unit 25, an imaging unit (not illustrated), and a control unit (not illustrated).

The holding table 22 has a disk shape, and a flat holding surface 23 that holds the ingot 1 along a horizontal direction is formed of porous ceramic or the like. The holding table 22 is provided to be movable over a processing region below the laser beam irradiation unit 25 and a carry-in/out region spaced from below the laser beam irradiation unit 25 and where the ingot 1 is carried in and out by moving units 28 and 29 provided on a device main body 21.

In the holding table 22, the holding surface 23 is connected to a vacuum suction source (not illustrated) and is sucked by the vacuum suction source to suck and hold the ingot 1 placed on the holding surface 23.

In the first embodiment, the holding table 22 is moved relative to the laser beam irradiation unit 25 by the moving units 28 and 29 located on the device main body 21. The holding table 22 is moved along a Y-axis direction parallel to the horizontal direction by the Y-axis moving unit 28 located on the device main body 21. The Y-axis moving unit 28 is located on the device main body 21, and moves the holding table 22 in the Y-axis direction by moving a moving plate 24 in the Y-axis direction on which the X-axis moving unit 29 is located.

The holding table 22 is moved in an X-axis direction parallel to the horizontal direction and perpendicular to the Y-axis direction by the X-axis moving unit 29 located on the moving plate 24. The X-axis moving unit 29 is located on the moving plate 24, and moves the holding table 22 in the X-axis direction by moving a second moving plate 27 in the X-axis direction on which a rotary moving unit 30 is located.

The holding table 22 rotates about a central axis parallel to a Z-axis direction by the rotary moving unit 30, the Z-axis direction being parallel to a vertical direction. The rotary moving unit 30 is located on the second moving plate 27 and supports the holding table 22 to rotate the holding table 22 about the central axis.

The Y-axis moving unit 28 moves the X-axis moving unit 29, the second moving plate 27, the rotary moving unit 30, and the holding table 22 in the Y-axis direction together with the moving plate 24. The X-axis moving unit 29 moves the rotary moving unit 30 and the holding table 22 in the X-axis direction together with the second moving plate 27.

The Y-axis moving unit 28 and the X-axis moving unit 29 include a well-known ball screw provided to be rotatable about the central axis, a well-known motor that rotates the ball screw about the central axis, and a well-known guide rail that supports the moving plates 24 and 27 to be rotatable in the X-axis direction or the Y-axis direction. The rotary moving unit 30 includes a well-known motor and the like that rotate the holding table 22 about the central axis.

As illustrated in FIG. 2, a part of the laser beam irradiation unit 25 is provided at a tip of a support column 32 of which a base end is supported by an erect column 31 erected from an end in the Y-axis direction of the device main body 21. The laser beam irradiation unit 25 is lifted and lowered by a lifting unit 33 that lifts and lowers the support column 32 provided in the erect column 31 in the Z-axis direction.

The lifting unit 33 lifts and lowers a part of the laser beam irradiation unit 25 in the Z-axis direction together with the support column 32. The lifting unit 33 includes a well-known ball screw provided to be rotatable about the central axis, a well-known motor that rotates the ball screw about the central axis, and a well-known guide rail that supports the support column 32 to be movable in the Z-axis direction.

As illustrated in FIG. 4, the laser beam irradiation unit 25 includes a laser oscillator 252 that emits a laser beam 251, an attenuator 253, a spatial light modulator 254, a mirror 255, and an irradiation head 256.

The laser oscillator 252 includes, for example, Nd:YAG as a laser medium, and emits the pulsed laser beam 251 having a wavelength that is transmitted through single crystal silicon (for example, 1064 nm). The attenuator 253 adjusts the laser beam 251 emitted from the laser oscillator 252, and supplies the adjusted laser beam 251 to the spatial light modulator 254.

The spatial light modulator 254 splits the laser beam 251. In the first embodiment, for example, the spatial light modulator 254 splits the laser beam 251 such that the laser beam 251 emitted from the irradiation head 256 described below forms a plurality of (for example, five) focal points arranged at regular intervals along the Y-axis direction.

The mirror 255 reflects the laser beam 251 split by the spatial light modulator 254 toward the irradiation head 256. The irradiation head 256 stores a condenser lens (not illustrated) or the like that focuses the laser beam 251. The irradiation head 256 emits the laser beam 251 focused by the condenser lens toward the holding surface 23 side of the holding table 22.

The imaging unit is disposed at the tip of the support column 32 and at a position beside the irradiation head 256 of the laser beam irradiation unit 25 in the X-axis direction. The imaging unit includes an imaging element that images a region to be divided in the ingot 1 before laser processing held on the holding table 22. The imaging element is, for example, a charge-coupled device (CCD) imaging element or a complementary MOS (CMOS) imaging element. The imaging unit images the ingot 1 held on the holding table 22, acquires an image for executing alignment of positioning the ingot 1 and the irradiation head 256 of the laser beam irradiation unit 25, and outputs the acquired image to the control unit.

The control unit controls each of the components in the laser processing device 20, and causes the laser processing device 20 to execute a processing operation on the ingot 1. The control unit is a computer that includes an arithmetic processing unit including a microprocessor such as a central processing unit (CPU), a storage device including a memory such as a read only memory (ROM) or a random access memory (RAM), and an input/output interface device. The arithmetic processing unit of the control unit executes arithmetic processing according to a computer program stored in the storage device, and outputs a control signal for controlling the laser processing device 20 to each of the components of the laser processing device 20 via the input/output interface device.

The control unit is connected to a display unit 34 constituted by a liquid crystal display device or the like that displays a state, an image, or the like of a processing operation and an input unit (not illustrated) used when an operator registers processing content information or the like. The input unit is constituted by at least one of a touch panel provided in the display unit 34 and an external input device such as a keyboard.

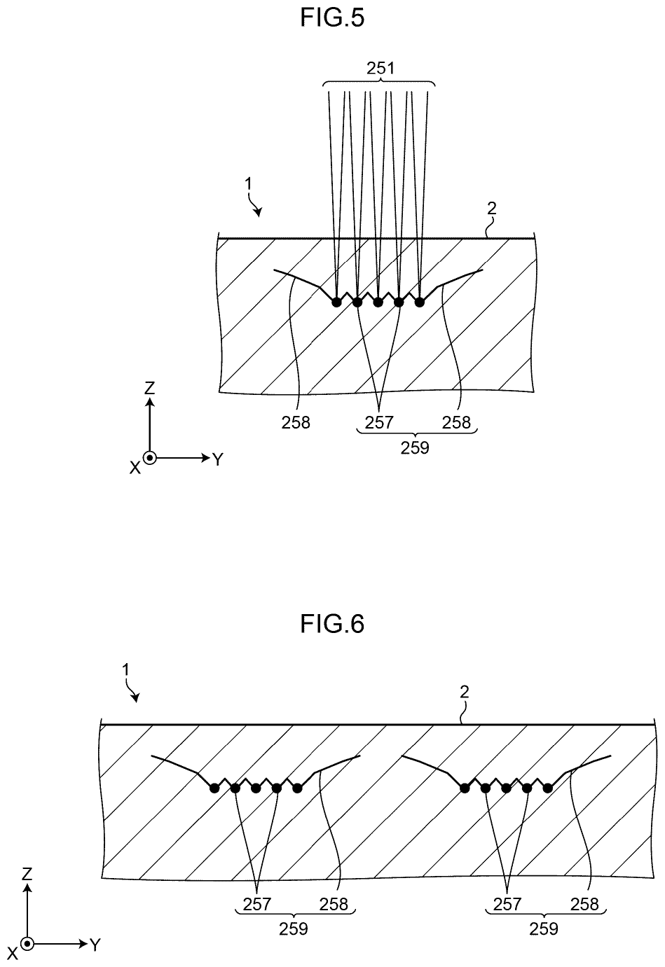

Next, the wafer forming step 1001 will be described. FIG. 5 is a cross-sectional view schematically illustrating a state where an ingot is irradiated with a laser beam in the wafer forming step of the ingot processing method illustrated in FIG. 2. FIG. 6 is a cross-sectional view schematically illustrating adjacent separation layers formed inside the ingot illustrated in FIG. 5.

The wafer forming step 1001 is a step of separating a part of the ingot 1 on the first surface 2 side to form a wafer 5 (illustrated in FIG. 1 and the like). In the first embodiment, in the wafer forming step 1001, as in JP 2023-27820 A, a part of the ingot 1 is separated as the wafer 5.

Specifically, in the first embodiment, in the wafer forming step 1001, the laser processing device 20 places the second surface 3 side on the holding surface 23 of the holding table 22 such that the first surface 2 of the ingot 1 is exposed, and sucks and holds the second surface 3 of the ingot 1 on the holding surface 23 of the holding table 22. In the first embodiment, in the wafer forming step 1001, the laser processing device 20 sets the focal points by a predetermined depth corresponding to the thickness of wafer 5 to be separated from the first surface 2, and irradiates the ingot 1 with the laser beam 251 while moving the holding table 22 and the irradiation head 256 relative to each other in the X-axis direction.

The laser beam 251 has been split, and the split laser beams are emitted in a condition where the focal points thereof are positioned inside the ingot 1. A modified region 257 where a crystal structure of single crystal silicon is disordered is formed around each of the focal points inside the ingot 1. That is, by irradiating the ingot 1 once with the laser beam 251 moving in the X-axis direction, a plurality of modified regions 257 are formed adjacent to each other in the Y-axis direction.

At this time, a crack 258 extends along a predetermined crystal plane from each of the plurality of modified regions 257. As a result, a separation layer 259 including the plurality of modified regions 257 and the crack 258 extending from the plurality of modified regions 257 is formed inside the ingot 1.

In the first embodiment, in the wafer forming step 1001, when the laser processing device 20 forms the separation layer 259 inside the ingot 1 over the entire length in the X-axis direction, the laser processing device 20 stops irradiation of the laser beam 251 and moves the ingot 1 and the irradiation head 256 by a predetermined distance in the Y-axis direction (hereinafter, referred to as index feeding). In the first embodiment, in the wafer forming step 1001, the laser processing device 20 repeats an operation of irradiating the entire length of the ingot 1 in the X-axis direction with the laser beam 251 and the index feeding until such separation layers 259 are formed entirely in positions having a predetermined depth from the first surface 2 of the ingot 1 as illustrated in FIG. 6.

In the first embodiment, in the wafer forming step 1001, when the separation layers 259 are formed entirely in positions having the predetermined depth from the first surface 2 of the ingot 1, the first surface 2 and the second surface 3 are sucked and held to move in directions in which the first surface 2 side and the second surface 3 side are away from each other. As a result, since the separation layers 259 are formed entirely in positions having the predetermined depth from the first surface 2 of the ingot 1, a part of the ingot 1 on the first surface 2 side is separated to become the wafer 5.

In the wafer 5 separated from the ingot 1, a surface 7 separated from the ingot 1 is subjected to grinding, polishing, and the like. A surface of the ingot 1 from which the wafer 5 is separated is subjected to grinding, polishing, and the like, to form a new first surface 2 on the surface, and subsequently a part of the ingot 1 having a predetermined thickness from the new first surface 2 is separated as a different wafer 5. Hereinafter, the first surface 2 of the wafer 5 will be referred to as a front surface, the surface 7 of the wafer 5 separated from the ingot 1 will be referred to as a back surface on the rear surface of the front surface 2, and the outer peripheral surface 4 of the wafer 5 will be referred to as a side surface.

### Orientation Detection Step

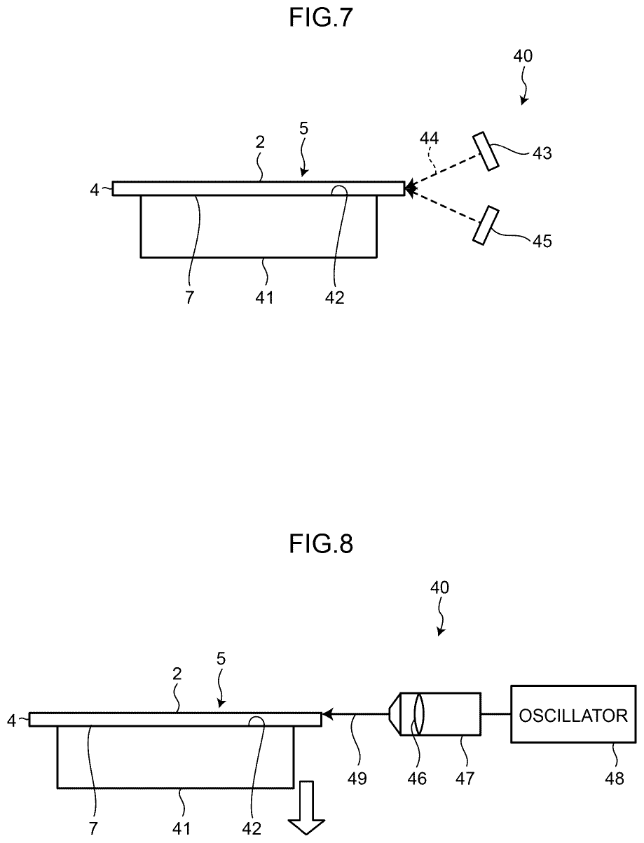

FIG. 7 is a side view schematically illustrating the orientation detection step of the ingot processing method illustrated in FIG. 2. The orientation detection step 1002 is a step of detecting a crystal orientation of the wafer 5. In the orientation detection step 1002, for example, as in JP 2000-266697 A, the crystal orientation of the wafer 5 is detected.

Specifically, in the first embodiment, in the orientation detection step 1002, a detection forming device 40 illustrated in FIG. 7 sucks and holds the wafer 5 on a flat disk-shaped holding surface 42 of a rotary table 41 that rotates about the central axis and has a smaller diameter than the wafer 5. In the first embodiment, in the orientation detection step 1002, the detection forming device 40 causes an X-ray 44 from an X-ray irradiation unit 43 to be incident on the side surface 4 of the wafer 5 held on the rotary table 41 while rotating the rotary table 41 about the central axis, and receives the reflected X-ray 44 with an X-ray receiving unit 45. In the first embodiment, in the orientation detection step 1002, the detection forming device 40 illustrated in FIG. 7 detects the crystal orientation of the wafer 5 based on an intensity of the X-ray 44 received by the X-ray receiving unit 45.

### Linear Flat Mirror Surface Portion Forming Step

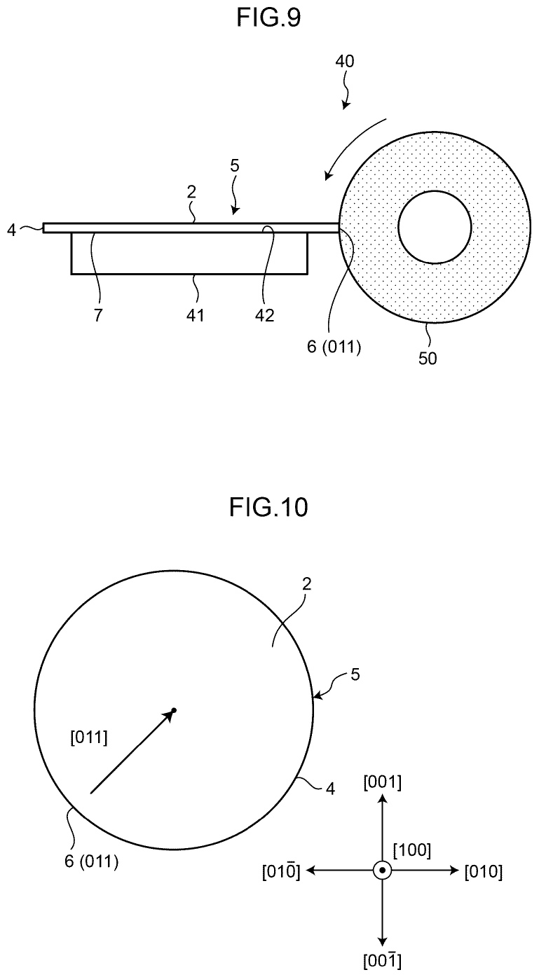

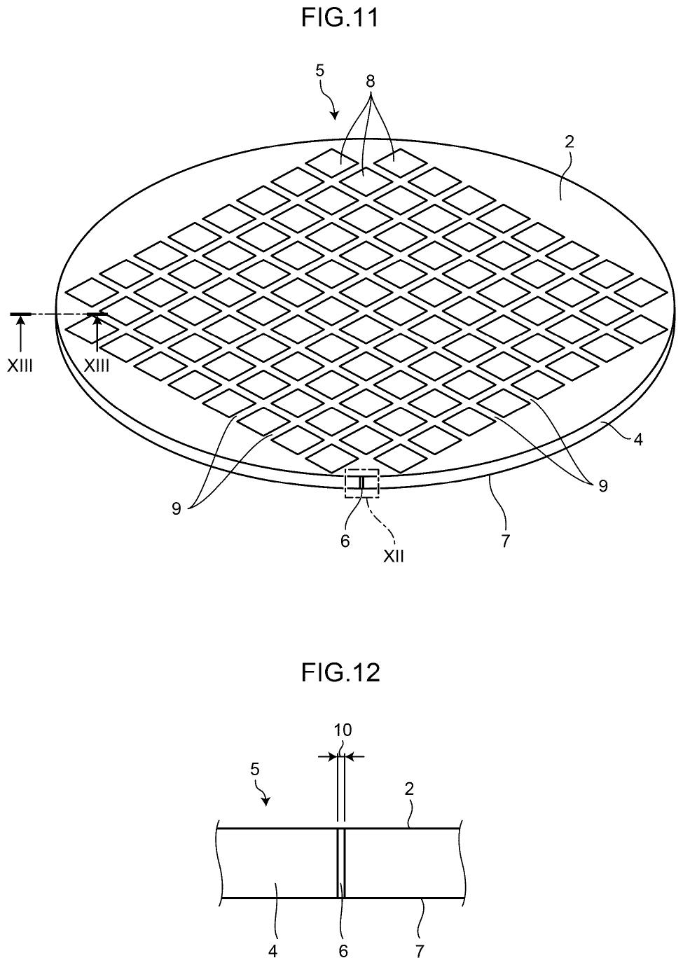

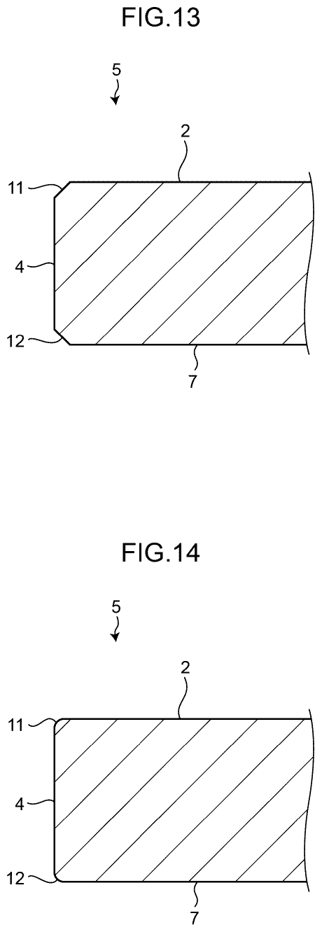

FIG. 8 is a side view schematically illustrating the linear flat mirror surface portion forming step of the ingot processing method illustrated in FIG. 2. FIG. 9 is a side view schematically illustrating a modification example of the linear flat mirror surface portion forming step of the ingot processing method illustrated in FIG. 8. FIG. 10 is a plan view schematically illustrating a crystal orientation of a wafer where a linear flat mirror surface portion is formed in the linear flat mirror surface portion forming step of the ingot processing method illustrated in FIG. 2. FIG. 11 is a perspective view schematically illustrating a crystal orientation of a wafer on which devices are formed in the linear flat mirror surface portion forming step of the ingot processing method illustrated in FIG. 2. FIG. 12 is a side view illustrating a portion XII in FIG. 11. FIG. 13 is a cross-sectional view of the wafer taken along a line XIII-XIII in FIG. 11. FIG. 14 is a cross-sectional view illustrating a modification example of the wafer illustrated in FIG. 13.

The linear flat mirror surface portion forming step 1003 is a step of forming a linear flat mirror surface portion 6 (corresponding to a flat mirror surface portion) along a thickness direction of the wafer 5 that is an extending direction of the ingot 1 based on the crystal orientation of the wafer 5 detected in the orientation detection step 1002. In the first embodiment, in the linear flat mirror surface portion forming step 1003, as illustrated in FIG. 8, the detection forming device 40 causes a laser processing head 47 including a focusing unit 46 to face a desired position of the side surface 4 of the wafer 5 based on the detected crystal orientation of the wafer 5.

In the first embodiment, in the linear flat mirror surface portion forming step 1003, the detection forming device 40 positions the laser processing head 47 along the crystal orientation [011] of the wafer 5 facing the (011) plane of the wafer 5. In the first embodiment, in the linear flat mirror surface portion forming step 1003, the detection forming device 40 irradiates the desired position of the side surface 4 of the wafer 5 with a laser beam 49 emitted from an oscillator 48 through the laser processing head 47 and having a wavelength of absorption with respect to the wafer 5, while relatively moving the wafer 5 held on the rotary table 41 and the laser processing head 47 in the thickness direction of the wafer 5.

As such, in the first embodiment, in the linear flat mirror surface portion forming step 1003, the detection forming device 40 performs laser processing on a position along the (011) plane perpendicular to the crystal orientation [011] of the wafer 5 on the side surface 4 of the wafer 5, and forms the linear flat mirror surface portion 6 extending over the entire length of the thickness direction in the thickness direction of the wafer 5 at the position along the (011) plane of the side surface 4 of the wafer 5.

In the present invention, in the linear flat mirror surface portion forming step 1003, as illustrated in FIG. 9, the detection forming device 40 may allow a dicing blade 50 to cut into a desired position of the side surface 4 of the wafer 5 while relatively moving the wafer 5 held on the rotary table 41 and the dicing blade 50 in the thickness direction of the wafer 5, so that the linear flat mirror surface portion 6 is formed.

As such, in the first embodiment, in the linear flat mirror surface portion forming step 1003, by forming the linear flat mirror surface portion 6 along the (011) plane on the side surface 4 of the wafer 5, the linear flat mirror surface portion 6 of the wafer 5 is formed based on the crystal orientation of the wafer 5, and the linear flat mirror surface portion 6 is formed such that the linear flat mirror surface portion 6 and the crystal orientation of the wafer 5 have a predetermined positional relationship as illustrated in FIG. 10. In the first embodiment, in the linear flat mirror surface portion forming step 1003, the linear flat mirror surface portion 6 is formed such that the crystal orientation of the wafer 5 and the linear flat mirror surface portion 6 have the positional relationship illustrated in FIG. 10. In the present invention, as long as the linear flat mirror surface portion 6 has a given positional relationship with the crystal orientation of the wafer 5, the positional relationship between the linear flat mirror surface portion 6 formed in the linear flat mirror surface portion forming step 1003 and the crystal orientation of the wafer 5 is not limited to the example illustrated in FIG. 10.

In the present invention, the linear flat mirror surface portion 6 may be formed by laser processing or the like after performing laser processing on the wafer 5 separated from the ingot 1 to correct the outer diameter. In the present invention, the linear flat mirror surface portion 6 may be formed on a part of the wafer 5 in the thickness direction instead of the entire area of the wafer 5 in the thickness direction (it is desirable that the linear flat mirror surface portion 6 is formed between the front surface 2 and a position closer to the front surface 2 than the center in the thickness direction).

Then, in the wafer 5, chamfering or the like is performed on the outer peripheral surface 4, and devices 8 are formed on the front surface 2 as illustrated in FIG. 11. The devices 8 are formed in regions divided by a plurality of planned division lines 9 intersecting each other on the front surface 2. In the present invention, after detection of crystal orientation of the wafer 5 and chamfering, the linear flat mirror surface portion 6 may be formed.

Examples of the devices 8 include an integrated circuit (IC), a large scale integration (LSI), an image sensor such as a charge coupled device (CCD) or a complementary metal oxide semiconductor (CMOS), and a memory (semiconductor storage device).

As such, the wafer 5 is obtained, the wafer 5 including the front surface 2, the back surface 7 on the rear surface of the front surface 2, and the side surface 4 that ranges from the front surface 2 to the back surface 7, and including the linear flat mirror surface portion 6 indicating the crystal orientation of the wafer 5 on the side surface 4, in which the linear flat mirror surface portion 6 is formed in a linear shape in a region from the front surface 2 side to the back surface 7 on the side surface 4 of the wafer 5.

In the first embodiment, a width 10 (illustrated in FIG. 12) of the linear flat mirror surface portion 6 is 0.05 mm or more and 34.5 mm or less. The reason for setting the width 10 of the linear flat mirror surface portion 6 to be 0.05 mm or more and 34.5 mm or less is that, when the width 10 of the linear flat mirror surface portion 6 is less than 0.05 mm, the linear flat mirror surface portion 6 cannot be detected in the detection step 1004, and when the width 10 of the linear flat mirror surface portion 6 is more than 34.5 mm, the number of the devices 8 formed on the front surface 2 of the wafer 5 is reduced to ensure the strength of the wafer 5 during the grinding of the wafer 5 in the grinding step 1005, which is undesirable.

In the present invention, the width 10 of the linear flat mirror surface portion 6 is preferably 0.05 mm or more and 10 mm or less and more preferably 0.05 mm or more and 5 mm or less. In short, it is desirable that the width 10 of the linear flat mirror surface portion 6 is as narrow as possible while being 0.05 mm or more so that the number of the devices 8 formed on the front surface 2 of the wafer 5 are not reduced to ensure the strength of the wafer 5 during the grinding of the wafer 5 in the grinding step 1005. In the first embodiment, the width 10 of the linear flat mirror surface portion 6 is 1 mm, and the thickness of the wafer 5 is 900 μm or more.

In the first embodiment, as illustrated in FIG. 13, the side surface 4 of the wafer 5 is a straight line in a vertical section that is a cross section passing through the central axis of the wafer 5, in which a front-surface side chamfered portion 11 is formed at a corner of the front surface 2 and the side surface 4 and a back-surface side chamfered portion 12 is formed at a corner of the back surface 7 and the side surface 4. The chamfered portions 11 and 12 are formed to be tapered such that the diameter of the wafer 5 decreases toward the front surface 2 or the back surface 7 in the above-described vertical section of the wafer 5. In the first embodiment, the chamfered portions 11 and 12 are formed by C-chamfering of C 0.2 mm or less.

In the present invention, as illustrated in FIG. 14, in the vertical section of the wafer 5, the front-surface side chamfered portion 11 may be formed in an arc shape continuing from the front surface 2 to the side surface 4, and the back-surface side chamfered portion 12 may also be formed in an arc shape continuing from the back surface 7 to the side surface 4. In the case illustrated in FIG. 14, the chamfered portions 11 and 12 are formed by R-chamfering of R 0.2 mm or less. In the case illustrated in FIG. 14, the chamfered portions 11 and 12 have, for example, a curvature radius less than ½ of the thickness of the wafer 5 (because when the curvature radius is ½ or more of the thickness of the wafer 5, the number of the devices 8 is reduced) and preferably have a curvature radius ⅓ or less and 1/100 or more of the thickness of the wafer 5 (because when the curvature radius is less than 1/100 of the thickness of the wafer 5, the wafer 5 is broken during handling).

The wafer forming step 1001, the orientation detection step 1002, and the linear flat mirror surface portion forming step 1003 described above constitute a preparation step 2001 of preparing the wafer 5 including the front surface 2, the back surface 7 on the rear surface of the front surface 2, and the side surface 4 that ranges from the front surface 2 to the back surface 7 and including the linear flat mirror surface portion 6 indicating the crystal orientation of the wafer 5 on the side surface 4.

### Grinding Device

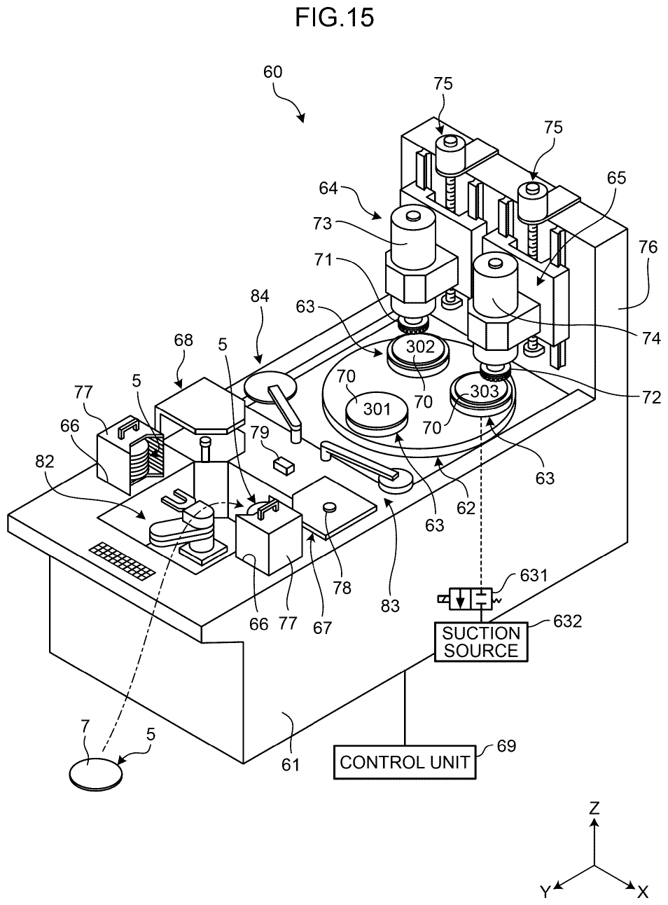

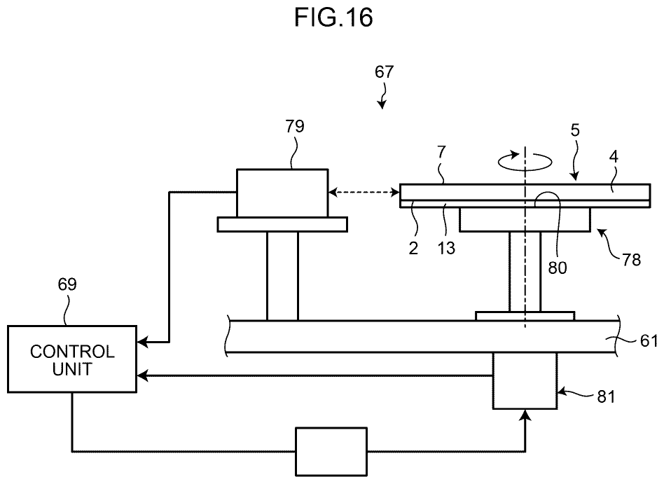

FIG. 15 is a perspective view schematically illustrating a configuration example of a grinding device used in the grinding step and the like of the ingot processing method illustrated in FIG. 2. FIG. 16 is a side view schematically illustrating a configuration of a detection unit of the grinding device illustrated in FIG. 15. In the detection step 1004, the grinding step 1005, and the storage step 1006, a grinding device 60 illustrated in FIG. 15 is used.

Next, the grinding device 60 will be described. As illustrated in FIG. 15, the grinding device 60 includes a device base 61, a turntable 62, for example, three holding tables 63 provided on the turntable 62, a rough grinding unit 64, a fine grinding unit 65, a cassette mount 66, a detection unit 67, a cleaning unit 68, and a control unit 69.

The turntable 62 is a disk-shaped table provided on an upper surface of the device base 61, is provided to be rotatable about the central axis parallel to the Z-axis direction in a horizontal plane, and is rotationally driven at a predetermined timing. The Z-axis direction is a direction parallel to the vertical direction. On the turntable 62, for example, three holding tables 63 are disposed at regular intervals at a phase angle of, for example, 120 degrees. That is, on the turntable 62, a plurality of holding tables 63 are disposed at regular angular intervals (for example, in the first embodiment, 120 degrees) in a peripheral direction.

The three holding tables 63 each has an upper surface formed of a porous material such as a porous ceramic as a holding surface 70 on which the wafer 5 is placed. In the holding table 63, the holding surface 70 is connected to a suction source 632 via an on-off valve 631 and the holding surface 70 is sucked by the suction source 632 such that the wafer 5 placed on the holding surface 70 is sucked and held on the holding surface 70.

The holding tables 63 are rotationally driven about the central axis parallel to the Z-axis direction by a rotation mechanism during processing. The holding table 63 is sequentially moved to a carry-in/out position 301, a rough grinding position 302, a fine grinding position 303, and the carry-in/out position 301 by rotation of the turntable 62.

The carry-in/out position 301 is a region where the wafer 5 is carried into and out of the holding table 63. The rough grinding position 302 is a region where the wafer 5 held on the holding table 63 is subjected to rough grinding (corresponding to processing) by the rough grinding unit 64. The fine grinding position 303 is a region where the wafer 5 held on the holding table 63 is subjected to fine grinding (corresponding to processing) by the fine grinding unit 65.

The rough grinding unit 64 is disposed above the holding table 63 positioned at the rough grinding position 302. The rough grinding unit 64 is a grinding unit that roughly grinds the back surface 7 of the wafer 5 held on the holding surface 70 of the holding table 63 at the rough grinding position 302. A grinding wheel 71 for rough grinding is attached to the rough grinding unit 64. The grinding wheel 71 has grinding abrasive products for rough grinding that are annularly arranged to roughly grind the back surface 7 of the wafer 5 exposed to an upper side of the wafer 5 held on the holding table 63.

The fine grinding unit 65 is disposed above the holding table 63 positioned at the rough grinding position 302. The fine grinding unit 65 a grinding unit that finely grinds the back surface 7 of the wafer 5 held on the holding surface 70 of the holding table 63 at the fine grinding position 303. A grinding wheel 72 has for fine grinding is attached to the fine grinding unit 65. The grinding wheel 72 has grinding abrasive products for fine grinding that are annularly arranged to finely grind the back surface 7 of the wafer 5 held on the holding table 63.

The grinding units 64 and 65 can be mounted on lower ends of spindles that rotate the grinding wheels 71 and 72 about their respective central axes parallel to the Z-axis direction by motors 73 and 74. The grinding units 64 and 65 are mounted on the lower ends of the spindles of the grinding wheels 71 and 72, and the grinding abrasive products of the grinding wheels 71 and 72 are disposed facing the holding surface 70 of the holding table 63. In the first embodiment, the outer diameter of a wheel portion constituted by the grinding abrasive products of each of the grinding wheels 71 and 72 is less than ½ of the outer diameter of the wafer 5.

The grinding unit 64 roughly grinds the back surface 7 of the wafer 5 when the spindle and the grinding wheel 71 rotates about the central axis by the motor 73 and the grinding abrasive products are brought closer to the holding table 63 by a grinding feed unit 75 at a predetermined feed rate while supplying water from a nozzle (not illustrated) to the back surface 7 of the wafer 5 held on the holding table 63 at the grinding position 302. The grinding unit 65 finely grinds the back surface 7 of the wafer 5 when the spindle and the grinding wheel 72 rotates about the central axis by the motor 74 and the grinding abrasive products are brought closer to the holding table 63 by a grinding feed unit 75 at a predetermined feed rate while supplying water from a nozzle (not illustrated) to the back surface 7 of the wafer 5 held on the holding table 63 at the grinding position 303.

The grinding feed units 75 that move the grinding units 64 and 65 in the Z-axis direction relatively close to or away from the holding table 63 are provided in an erect plate 76 erected from one end of the device base 61 in the X-axis direction parallel to the horizontal direction. The grinding feed units 75 each include a well-known ball screw provided to be rotatable about the central axis, a well-known motor that rotates the ball screw about the central axis, and a well-known guide rail that supports a spindle housing of each of the grinding units 64 and 65 to be movable in the Z-axis direction.

In the first embodiment, in each of the rough grinding unit 64 and the fine grinding unit 65, the central axis that is the center of rotation of the grinding wheel 71 or 72 and the central axis that is the center of rotation of the holding table 63 are arranged in parallel to each other with a space therebetween in the horizontal direction, and the grinding abrasive products passes through the center of the back surface 7 of the wafer 5 held on the holding table 63.

A wafer cassette 77 is placed on the cassette mount 66. The wafer cassette 77 includes a plurality of slots and is a storage container for storing a plurality of wafers 5. The wafer cassette 77 stores the plurality of wafers 5 before and after grinding. In the first embodiment, a pair of cassette mounts 66 are provided, and the wafer cassette 77 is placed on each of the cassette mounts 66. The cassette mount 66 supports the wafer cassette 77 to be lifted and lowered along the Z-axis direction.

The detection unit 67 includes a holding table 78 on which the wafer 5 before grinding taken out from the wafer cassette 77 is temporarily placed. The detection unit 67 includes the holding table 78 and an optical sensor 79 as illustrated in FIG. 16.

The holding table 78 is located on the device base 61, has a disk shape, and includes a holding surface 80 being flat along the horizontal direction and formed of porous ceramic or the like. The holding table 78 is rotated about the central axis parallel to the Z-axis direction by a motor 81 located on the device base 61. The motor 81 is equipped with an encoder capable of detecting an angle of the holding table 78. The encoder of the motor 81 outputs the detected angle of the holding table 78 to the control unit 69. In the holding table 78, the holding surface 80 is connected to a vacuum suction source (not illustrated) and is sucked by the vacuum suction source to suck and hold the wafer 5 placed on the holding surface 80.

The optical sensor 79 is located on the device base 61 and faces, along the horizontal direction, the side surface 4 of the wafer 5 held on the holding table 78. The optical sensor 79 includes a light emitting unit that emits light toward the side surface 4 of the wafer 5 held on the holding table 78, a light receiving unit that receives light reflected from the side surface 4, and a light intensity detection unit that detects intensity of the reflected light received by the light receiving unit and outputs the detected intensity to the control unit 69.

The cleaning unit 68 cleans the wafer 5 after grinding, and removes contamination such as processing particles attached to the ground and polished back surface 7.

The grinding device 60 includes a first carrier unit 82. The first carrier unit 82 takes out the wafer 5 before grinding from the wafer cassette 77, carries the wafer 5 to the holding table 78 of the detection unit 67, carries the wafer 5 after grinding from the cleaning unit 68 to the holding table 78 of the detection unit 67, and carries the wafer 5 from the holding table 78 of the detection unit 67 to the wafer cassette 77. The first carrier unit 82 is, for example, a robot pick including a U-shaped hand and carries the wafer 5 by suction and holding by the U-shaped hand.

The grinding device 60 includes a second carrier unit 83 and a third carrier unit 84. The second carrier unit 83 carries the wafer 5 before grinding on the holding table 78 of the detection unit 67 onto the holding table 63 positioned at the carry-in/out position 301. The third carrier unit 84 carries the wafer 5 after grinding on the holding table 63 positioned at the carry-in/out position 301 to the cleaning unit 68. The carrier units 83 and 84 each include a vacuum pad for sucking the wafer 5, and carry the wafer 5 by suction and holding by the vacuum pad.

The control unit 69 controls each of the above-described units constituting the grinding device 60 and causes the grinding device 60 to execute the processing operation on the wafer 5. The control unit 69 is a computer that includes an arithmetic processing unit including a microprocessor such as a central processing unit (CPU), a storage device including a memory such as a read only memory (ROM) or a random access memory (RAM), and an input/output interface device.

The arithmetic processing unit of the control unit 69 executes arithmetic processing according to a computer program stored in the storage device, and outputs a control signal for controlling the grinding device 60 to the above-described components of the grinding device 60 via the input/output interface device. The control unit 69 is connected to a display unit constituted by a liquid crystal display device or the like for displaying a state, an image, or the like of a processing operation, an input unit (not illustrated) used when an operator registers processing content information or the like, and a notification unit for notification to the operator.

The input unit is constituted by at least one among a touch panel provided in the display unit, and a keyboard and the like. The notification unit outputs at least any of sound, light, and a message on the touch panel for notification to the operator.

### Detection Step

Next, the detection step 1004 will be described. In the first embodiment, the detection step 1004 is a step of detecting the linear flat mirror surface portion 6 before executing the grinding step 1005. In the first embodiment, in the detection step 1004, a tape 13 as a protective member formed of resin is attached to the front surface 2 of the wafer 5, and the wafer 5 to which the tape 13 is attached is stored in the wafer cassette 77. At this time, the front surface 2 of the wafer 5 to which the tape 13 is attached is positioned downward, and the back surface 7 is exposed upward.

In the first embodiment, in the detection step 1004, the grinding device 60 starts the processing operation when the wafer cassette 77 storing the wafer 5 having the front surface 2 to which the tape 13 is attached is placed on the cassette mount 66, processing conditions are registered in the control unit 69 by the operator, and the control unit 69 receives a start instruction of the processing operation from the operator.

In the first embodiment, in the detection step 1004, the control unit 69 of the grinding device 60 rotates the spindle of each of the grinding units 64 and 65 about the central axis at a rotating speed determined based on processing conditions. In the first embodiment, in the detection step 1004, the grinding device 60 takes out one wafer 5 from any of the wafer cassettes 77 to the first carrier unit 82, and carries the wafer 5 onto the holding table 78 of the detection unit 67.

In the first embodiment, in the detection step 1004, the grinding device 60 causes the holding surface 80 of the holding table 78 of the detection unit 67 to suck and hold the front surface 2 side of the wafer 5 via the tape 13, causes the light emitting unit of the optical sensor 79 to emit light and the light receiving unit to receive the reflected light while rotating the holding table 78, i.e., the wafer 5, about the central axis with the motor 81. In the first embodiment, in the detection step 1004, the grinding device 60 stops the rotation of the holding table 78 about the central axis at an angle where the intensity is the maximum based on the detection result of the light intensity detection unit of the optical sensor 79 of the detection unit 67.

As such, in the first embodiment, in the detection step 1004, the grinding device 60 stops the rotation of the holding table 78 about the central axis at an angle where the intensity is the maximum based on the detection result of the light intensity detection unit of the optical sensor 79 of the detection unit 67 so that the linear flat mirror surface portion 6 is detected, and the wafer 5 is positioned such that the linear flat mirror surface portion 6 is in a predetermined orientation with respect to the second carrier unit 83. In the present invention, the detection step 1004 may be executed after executing the grinding step 1005.

### Grinding Step

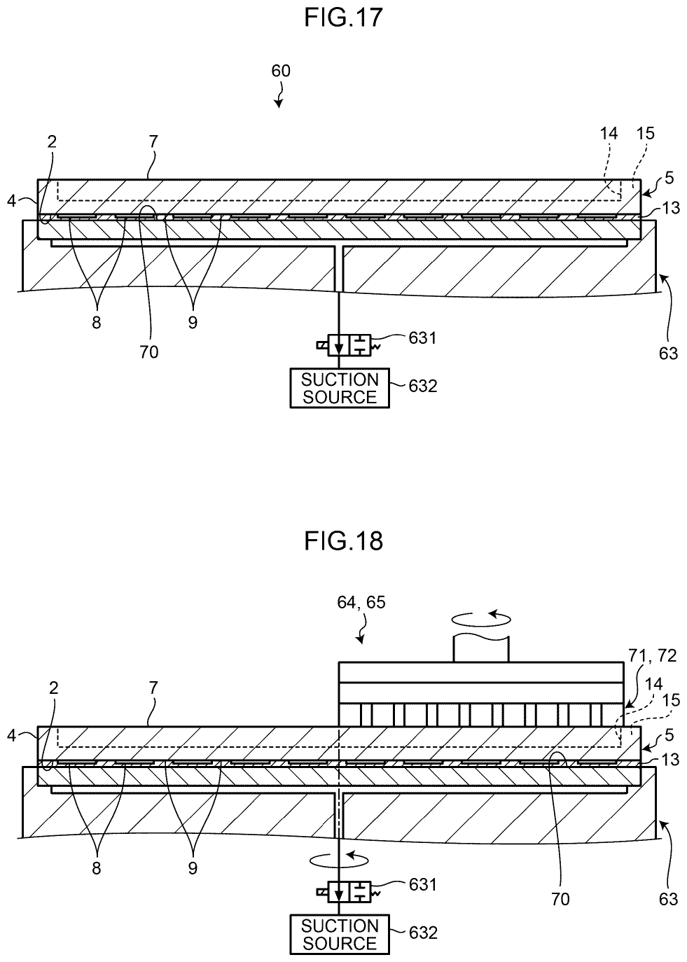

Next, the grinding step 1005 will be described. FIG. 17 is a cross-sectional view schematically illustrating a state where the holding table of the grinding device holds the wafer in the grinding step of the ingot processing method illustrated in FIG. 2. FIG. 18 is a cross-sectional view schematically illustrating a state where the grinding unit of the grinding device grinds the wafer in the grinding step of the ingot processing method illustrated in FIG. 2.

The grinding step 1005 is a step of grinding the back surface 7 of the wafer 5 prepared in the preparation step 2001 to form a recess 14 and form a projection 15 surrounding the recess 14 on the back surface 7. In the first embodiment, in the grinding step 1005, the grinding device 60 stops suction and holding of the wafer 5 on the holding table 78 of the detection unit 67.

In the first embodiment, in the grinding step 1005, the control unit 69 of the grinding device 60 causes the vacuum pad of the second carrier unit 83 to suck and hold the wafer 5 on the holding table 78 of the detection unit 67, and causes the second carrier unit 83 to carry in the wafer 5 to the holding surface 70 of the holding table 63 positioned at the carry-in/out position 301. At this time, the second carrier unit 83 carries the wafer 5 onto the holding table 63 such that the wafer 5 is in a certain orientation with respect to the holding table 63. In the first embodiment, in the grinding step 1005, as illustrated in FIG. 17, the control unit 69 of the grinding device 60 causes the holding surface 70 of the holding table 63 positioned at the carry-in/out position 301 to suck and hold the wafer 5 via the tape 13.

In the first embodiment, in the grinding step 1005, the control unit 69 of the grinding device 60 rotates the turntable 62, and carries the holding table 63 holding the wafer 5 at the carry-in/out position 301 to the rough grinding position 302 and the fine grinding position 303 in this order. In the first embodiment, in the grinding step 1005, at the rough grinding position 302 and the fine grinding position 303, as illustrated in FIG. 18, the grinding device 60 sequentially performs rough grinding and fine grinding on the back surface 7 of the wafer 5 with the grinding abrasive products, by supplying water while causing the spindles to rotate the grinding wheels 71 and 72 and rotate the holding tables 63 about the central axes, and by causing the grinding abrasive products to abut against the back surface 7 of the wafer 5 and bringing the grinding abrasive products close to the holding table 63 at a predetermined feed rate.

In the first embodiment, in the grinding step 1005, the outer diameter of each of the grinding wheels 71 and 72 is less than ½ of the outer diameter of the wafer 5 such that the outer edge of the back surface 7 of the wafer 5 remains and the annular projection 15 is formed, and the inner periphery of the projection 15 is ground such that the circular recess 14 is formed inside the inner periphery of the projection 15. In the first embodiment, in the grinding step 1005, the grinding device 60 causes the grinding units 64 and 65 to grind the back surface 7 of the wafer 5 until the thickness of the recess 14 reaches a predetermined thickness. When the grinding by the grinding units 64 and 65 ends, in the first embodiment, in the grinding step 1005, the grinding device 60 positions the ground wafer 5 at the carry-in/out position 301.

As such, in the first embodiment, in the grinding step 1005, by attaching the tape 13 formed of resin to the front surface 2 of the wafer 5, the wafer 5 is ground without disposing a hard plate on the front surface 2 of the wafer 5. In the first embodiment, the width of the projection 15 in the radial direction of the wafer 5 is 0.15% or more and 0.5% or less of the diameter of the wafer 5. The reason why the width of the projection 15 in the radial direction of the wafer 5 is 0.15% or more and 0.5% or less of the diameter of the wafer 5 is that, when the width of the projection 15 in the radial direction of the wafer 5 is less than 0.15% of the diameter of the wafer 5, the wafer 5 is broken while being carried, and when the width of the projection 15 in the radial direction of the wafer 5 is more than 0.5% of the diameter of the wafer 5, the number of the devices 8 is reduced.

### Storage Step

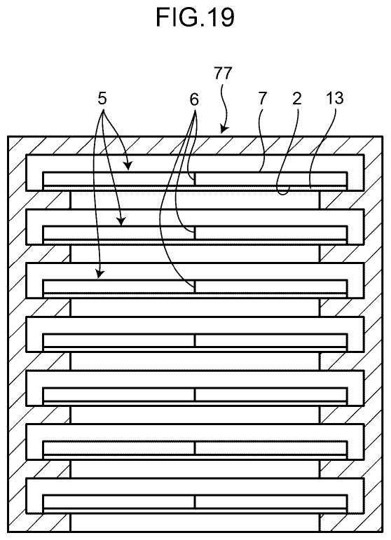

FIG. 19 is a front view schematically illustrating the wafer cassette in which the wafer is stored in the storage step of the ingot processing method illustrated in FIG. 2. The storage step 1006 is a step of storing the wafer 5 in the wafer cassette 77 after executing the detection step 1004 and the grinding step 1005.

In the first embodiment, in the storage step 1006, the grinding device 60 stops suction and holding of the wafer 5 after grinding on the holding table 63 positioned at the carry-in/out position 301, and causes the second carrier unit 83 to carry the wafer 5 from the holding table 63 positioned at the carry-in/out position to the cleaning unit 68. In the first embodiment, in the storage step 1006, the grinding device 60 causes the cleaning unit 68 to clean the wafer 5, and causes the first carrier unit 82 to carry the wafer 5 after cleaning into the wafer cassette 77.

In the first embodiment, in the detection step 1004 and the storage step 1006 performed in the grinding device 60, in all of the rough grinding, the fine grinding, and the cleaning in the cleaning unit 68, the grinding or cleaning is started in a state in which the holding table 63 and a spinner table of the cleaning unit 68 of the grinding device 60 are always in a certain orientation, the grinding or cleaning is stopped in a state in which the holding table 63 and the spinner table are in the same certain orientation after the end of grinding the cleaning, and the wafer 5 is carried while being in the same orientation in the grinding device 60 and is stored in the wafer cassette 77. Therefore, in the first embodiment, in the storage step 1006, as illustrated in FIG. 19, the grinding device 60 causes the first carrier unit 82 to store the wafer 5 in the wafer cassette 77 such that the linear flat mirror surface portion 6 is positioned at the center of the wafer 5 in the width direction when seen from the front of an opening through which the wafer 5 of the wafer cassette 77 is carried in and out.

Therefore, in the first embodiment, in the storage step 1006, in the grinding device 60, the linear flat mirror surface portions 6 of the wafers 5 after grinding stored in the wafer cassette 77 are aligned in the thickness direction of the wafer 5. As such, in the storage step 1006, the wafer 5 is stored in the wafer cassette 77 while the linear flat mirror surface portion 6 is positioned in a predetermined orientation with respect to the wafer cassette 77. The predetermined orientation in which the wafer 5 after grinding is stored in the wafer cassette 77 is not limited to the direction illustrated in FIG. 19.

As such, in the detection step 1004, the grinding step 1005, and the storage step 1006, the grinding device 60 detects the linear flat mirror surface portion 6 of the wafer 5, causes the turntable 62 to carry the wafer 5 to the rough grinding position 302, the fine grinding position 303, and the carry-in/out position 301 in this order, sequentially performs rough grinding and fine grinding, and causes the cleaning unit 68 to clean the wafer 5, and stores the wafer 5 in the wafer cassette 77. Each time the turntable 62 rotates by 120 degrees, the grinding device 60 takes out the wafer 5 after grinding from the holding table 63 positioned at the carry-in/out position 301, carries the wafer 5 before grinding onto the holding table 63 positioned at the carry-in/out position 301, roughly grinds the wafer 5 before rough grinding, and finely grinds the wafer 5 after rough grinding. When all of the wafers 5 in the wafer cassette 77 are ground, the grinding device 60 ends the processing operation.

The preparation step 2001, the detection step 1004, the grinding step 1005, and the storage step 1006 constitutes the wafer processing method according to the present invention.

In the wafer processing method and the ingot processing method according to the first embodiment described above, since the wafer 5 includes the linear flat mirror surface portion 6 on the side surface thereof, the crystal orientation can be specified without forming a notch or an orientation flat. Thus, the depth of the linear flat mirror surface portion 6 from the side surface 4 can be reduced as compared to a notch or an orientation flat, so that the recess 14 can be formed to be larger in area compared to a wafer in the related art in which a notch or an orientation flat is formed.

In the wafer processing method and the ingot processing method according to the first embodiment, the recess 14 can be formed having a larger area compared to a wafer in the related art in which a notch is formed, and thus, the number of the devices 8 that can be formed can be increased.

As a result, the wafer processing method and the ingot processing method according to the first embodiment is capable of forming a larger number of devices 8.

Currently, for example, a wafer having a large diameter of 300 mm is likely to be bent after grinding for forming the recess 14, so the wafer is ground while being fixed to a hard substrate. However, in the wafer processing method and the ingot processing method according to the first embodiment, the side surface 4 of the wafer 5 is formed in a straight line in the vertical section of the wafer, the front-surface side chamfered portion 11 is formed at a corner between the side surface 4 and the front surface 2, and the back-surface side chamfered portion 12 is formed at a corner between the side surface 4 and the back surface 7, so that the wafer 5 can be prevented from being bent after the grinding step 1005 for forming the recess 14, and the wafer 5 can be ground without fixing a hard substrate to the wafer 5.

In the wafer processing method according to the first embodiment, in the storage step 1006, the wafer 5 is stored in a predetermined orientation with respect to the wafer cassette 77, so that a step of detecting the orientation of the wafer 5 as the next step is unnecessary.

In the wafer 5 according to the first embodiment, the chamfered portions 11 and 12 are provided on the front and back surfaces 2 and 7 sides to be perpendicular to the side surface 4. Thus, unlike the wafer in the related art in which chamfering is performed in an arc shape from the front surface 2 to the back surface 7, the projection 15 functions as a reinforcement even when the width of the projection 15 is set to be narrower. Accordingly, in the wafer 5 according to the first embodiment, the recess 14 can be formed to be large in area, and a larger number of devices 8 can be formed.

In the wafer 5 according to the first embodiment, when the chamfered portions 11 and 12 are formed in the arc shape, the wafer 5 according to the first embodiment is not likely to be broken during handling even when the curvature radii of the chamfered portions 11 and 12 are set to be small.

The wafer 5 according to the first embodiment has a thickness of 900 μm or more, so the wafer 5 is not bent even after the grinding step 1005, and the substrate is unnecessary in the grinding step 1005.

### Second Embodiment

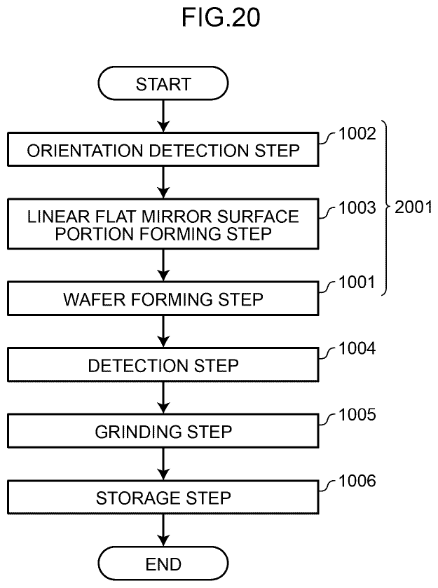

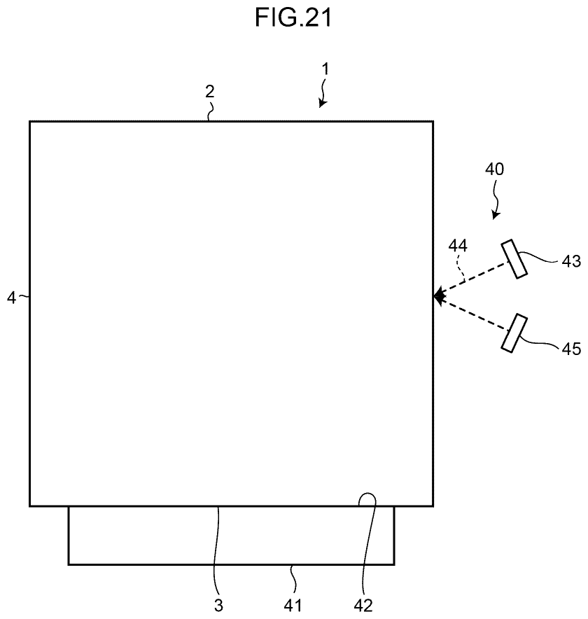

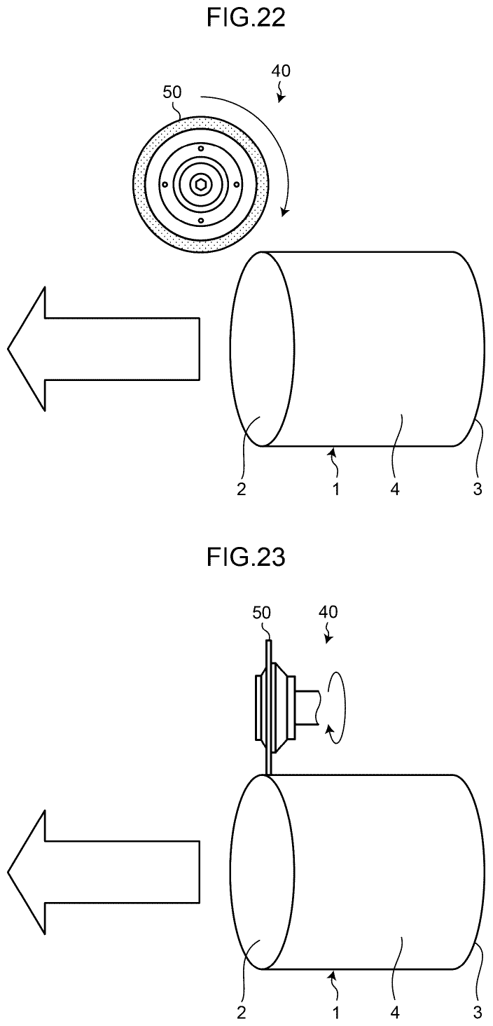

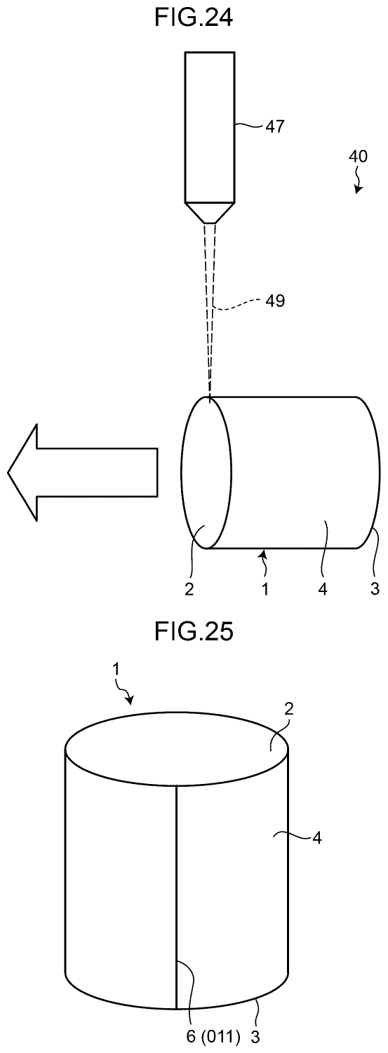

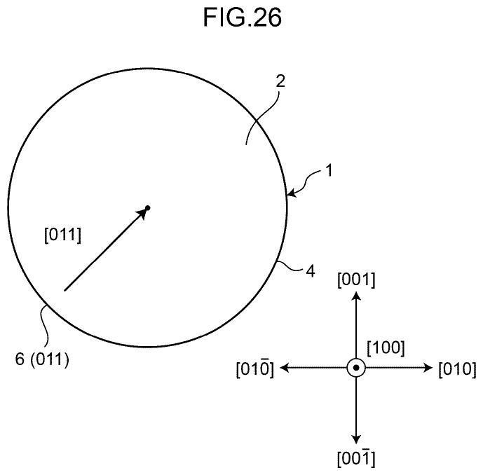

An ingot processing method according to a second embodiment will be described based on the drawings. FIG. 20 is a flowchart illustrating a flow of the ingot processing method according to the second embodiment. FIG. 21 is a side view schematically illustrating an orientation detection step of the ingot processing method illustrated in FIG. 20. FIG. 22 is a side view schematically illustrating a linear flat mirror surface portion forming step of the ingot processing method illustrated in FIG. 20. FIG. 23 is a side view schematically illustrating a modification example of the linear flat mirror surface portion forming step of the ingot processing method illustrated in FIG. 20. FIG. 24 is a side view schematically illustrating another modification example of the linear flat mirror surface portion forming step of the ingot processing method illustrated in FIG. 20. FIG. 25 is a perspective view schematically illustrating an ingot after the linear flat mirror surface portion forming step of the ingot processing method illustrated in FIG. 20. FIG. 26 is a plan view schematically illustrating a crystal orientation of an ingot on which a linear flat mirror surface portion is formed in the linear flat mirror surface portion forming step of the ingot processing method illustrated in FIG. 20. In FIGS. 20, 21, 22, 23, 24, 25, and 26, the same components as those of the first embodiment will be represented by the same reference numerals, and the description thereof will not be repeated.

As illustrated in FIG. 20, the ingot processing method according to the second embodiment is the same as that of the first embodiment except that the preparation step 2001 of the wafer processing method is different. In the preparation step 2001 of the ingot processing method according to the second embodiment, that is, the wafer processing method, as illustrated in FIG. 20, the orientation detection step 1002 is executed, the linear flat mirror surface portion forming step 1003 is executed after the orientation detection step 1002, and the wafer forming step 1001 is executed after the linear flat mirror surface portion forming step 1003.

In the second embodiment, the orientation detection step 1002 is a step of detecting a crystal orientation of the ingot 1. Also in the second embodiment, in the orientation detection step 1002, for example, as in JP 2000-266697 A, the crystal orientation of the ingot 1 is detected.

Specifically, in the second embodiment, in the orientation detection step 1002, the detection forming device 40 illustrated in FIG. 21 sucks and holds the second surface 3 of the ingot 1 on the flat holding surface 42 of the disk-shaped rotary table 41 that rotates about the central axis and has a smaller diameter than the ingot 1. In the first embodiment, in the orientation detection step 1002, the detection forming device 40 causes the X-ray 44 from an X-ray irradiation unit 43 to be incident on the outer peripheral surface 4 of the ingot 1 held on the rotary table 41 while rotating the rotary table 41 about the central axis, and receives the reflected X-ray 44 with the X-ray receiving unit 45. In the second embodiment, in the orientation detection step 1002, the detection forming device 40 illustrated in FIG. 21 detects the crystal orientation of the ingot 1 based on an intensity of the X-ray 44 received by the X-ray receiving unit 45.

In the second embodiment, the linear flat mirror surface portion forming step 1003 is a step of forming the linear flat mirror surface portion 6 along an extending direction (central axis) of the ingot 1 based on the crystal orientation detected in the orientation detection step 1002. In the second embodiment, in the linear flat mirror surface portion forming step 1003, as illustrated in FIGS. 22 and 23, the detection forming device 40 moves the dicing blade 50 and the ingot 1 relative to each other in the central axis direction of the ingot 1 based on the detected crystal orientation of the ingot 1, and causes the dicing blade 50 to cut into a desired position of the outer peripheral surface 4 of the ingot 1 over the entire length of the ingot 1 to form the linear flat mirror surface portion 6 over the entire length of the ingot 1.

In the second embodiment, in the linear flat mirror surface portion forming step 1003, the dicing blade 50 cuts into the position of the (011) plane of the outer peripheral surface 4 of the ingot 1. At this time, a cutting edge of the dicing blade 50 may be parallel to the central axis of the ingot 1, or the cutting edge of the dicing blade 50 may be perpendicular to the central axis of the ingot 1. It is desirable that the dicing blade 50 has a cutting edge of a higher number such as #4000. In the present invention, in the linear flat mirror surface portion forming step 1003, the linear flat mirror surface portion 6 may be polished after dicing with the dicing blade 50.

In the present invention, in the linear flat mirror surface portion forming step 1003 according to the second embodiment, as illustrated in FIG. 24, the desired position of the outer peripheral surface 4 of the ingot 1 (in the second embodiment, the position along the (011) plane perpendicular to the crystal orientation [011] of the wafer 5) may be irradiated with the laser beam 49 from the laser processing head 47 over the entire length of the ingot 1 to form the linear flat mirror surface portion 6 over the entire length of the ingot 1.

As such, in the second embodiment, in the linear flat mirror surface portion forming step 1003, as illustrated in FIG. 25, the linear flat mirror surface portion 6 is formed over the entire length of the ingot 1 at the position of the (011) plane of the outer peripheral surface 4 of the ingot 1. In the second embodiment, in the linear flat mirror surface portion forming step 1003, by forming the linear flat mirror surface portion 6 of the ingot 1 based on the crystal orientation of the ingot 1, the linear flat mirror surface portion 6 is formed such that the linear flat mirror surface portion 6 and the crystal orientation of the ingot 1 have a predetermined positional relationship as illustrated in FIG. 26.

In the second embodiment, in the linear flat mirror surface portion forming step 1003, the linear flat mirror surface portion 6 is formed such that the crystal orientation of the ingot 1 and the linear flat mirror surface portion 6 have the positional relationship illustrated in FIG. 26. In the present invention, the positional relationship between the linear flat mirror surface portion 6 formed in the linear flat mirror surface portion forming step 1003 and the crystal orientation of the ingot 1 is not limited to the example illustrated in FIG. 26.

In the second embodiment, the wafer forming step 1001 is executed after the linear flat mirror surface portion forming step 1003. Therefore, in the second embodiment, the wafer forming step 1001 is a step of separating a part of the ingot 1 to form the wafer 5 after executing the linear flat mirror surface portion forming step 1003. In the second embodiment, in the wafer forming step 1001, as in the first embodiment, a part of the ingot 1 is separated to form the wafer 5. In the second embodiment, in the wafer forming step 1001, it is desirable that the crystal orientation [011] of the ingot 1 held on the holding table 22 is parallel to the X-axis direction of the laser processing device 20 and the ingot 1 is irradiated with the laser beam 251 while moving the ingot 1 and the irradiation head 256 relative to each other along the X-axis direction, that is, the crystal orientation [010].

In the second embodiment, in the present invention, in the wafer forming step 1001, the linear flat mirror surface portion 6 may be detected and the crystal orientation [010] of the ingot 1 may be positioned to be parallel to the X-axis direction of the laser processing device 20 based on the detected position of the linear flat mirror surface portion 6. In the second embodiment, the detection step 1004, the grinding step 1005, and the storage step 1006 are sequentially executed using the grinding device 60 after the wafer forming step 1001 as in the first embodiment.

In the wafer processing method and the ingot processing method according to the second embodiment, the wafer 5 includes the linear flat mirror surface portion 6 on the side surface such that, as in the first embodiment, the crystal orientation can be specified without forming a notch or an orientation flat, the recess 14 can be formed to be larger in area compared to a wafer in the related art in which a notch or an orientation flat is formed, and a larger number of devices 8 can be formed.

Next, the effects of the ingot processing method, the wafer processing method, and the wafer 5 according to the first embodiment was confirmed. In confirmation, whether the wafer 5 is broken and the number of devices 8 were confirmed for Invention Product 1, Invention Product 2, Invention Product 3, Invention Product 4, Invention Product 5, Invention Product 6, Invention Product 7, Invention Product 8, Invention Product 9, Comparative Example 1, Comparative Example 2, and Comparative Example 3. The results are shown in Table 1 below.

TABLE 1

| | Breakage | Number of devices |
|---|---|---|
| Invention Product 1 | None | 636 |
| Invention Product 2 | None | 636 |
| Invention Product 3 | None | 636 |
| Invention Product 4 | None | 636 |
| Invention Product 5 | None | 626 |
| Invention Product 6 | None | 626 |
| Invention Product 7 | None | 626 |
| Invention Product 8 | None | 626 |
| Invention Product 9 | None | 626 |
| Comparative Example 1 | Reinforcement failed | 636 |
| Comparative Example 2 | Present | 626 |
| Comparative Example 3 | None | 621 |

In Invention Product 1, Invention Product 2, Invention Product 3, Invention Product 4, Invention Product 5, Invention Product 6, Invention Product 7, Invention Product 8, Invention Product 9, Comparative Example 1, Comparative Example 2, and Comparative Example 3, the thickness of the wafer 5 was 900 μm, and the diameter was 300 mm. In Invention Product 1, Invention Product 2, Invention Product 3, Invention Product 4, Invention Product 5, Invention Product 6, Invention Product 7, Invention Product 8, Invention Product 9, the side surface 4 and the chamfered portions 11 and 12 were formed. In Comparative Example 1, Comparative Example 2, and Comparative Example 3, the arc-shaped chamfered portion was formed across the front surface 2 and the back surface 7.

In Invention Product 1, Invention Product 2, Invention Product 3, Invention Product 4, Invention Product 5, Invention Product 6, Invention Product 7, Invention Product 8, Invention Product 9, Comparative Example 1, Comparative Example 2, and Comparative Example 3, the thickness of the recess 14 of the wafer 5 was 50 μm. In Invention Product 1, Invention Product 2, Invention Product 3, Invention Product 4, and Comparative Example 1, the width of the projection 15 of the wafer 5 was 0.15% of the diameter of the wafer 5. In Invention Product 5, Invention Product 6, Invention Product 7, Invention Product 8, Invention Product 9, and Comparative Example 2, the width of the projection 15 of the wafer 5 was 0.5% of the diameter of the wafer 5. In Comparative Example 3, the width of the projection 15 of the wafer 5 was 0.7% of the diameter of the wafer 5.

In Invention Product 1 and Invention Product 5, the width 10 of the linear flat mirror surface portion 6 of the wafer 5 was 0.05 mm. In Invention Product 2 and Invention Product 6, the width 10 of the linear flat mirror surface portion 6 of the wafer 5 was 1.0 mm. In Invention Product 3 and Invention Product 7, the width 10 of the linear flat mirror surface portion 6 of the wafer 5 was 5.0 mm. In Invention Product 4 and Invention Product 8, the width 10 of the linear flat mirror surface portion 6 of the wafer 5 was 10.0 mm. In Invention Product 9, the width 10 of the linear flat mirror surface portion 6 of the wafer 5 was 34.5 mm. In Comparative Example 1, Comparative Example 2, and Comparative Example 3, the width of the notch was 2 mm, the depth of the notch was 1 mm, and the angle of the notch was 90 degrees.

According to Table 1, in the wafer 5 of Comparative Example 1, the projection 15 was cut during grinding, was not able to function as a reinforcement, and was not able to prevent the breakage of the wafer 5 while being carried, and the wafer 5 of Comparative Example 2 was broken while being carried. In contrast, in Invention Product 1, Invention Product 2, Invention Product 3, Invention Product 4, Invention Product 5, Invention Product 6, Invention Product 7, Invention Product 8, Invention Product 9, and Comparative Example 3, the wafer 5 was not broken while being carried.

According to Table 1, the number of devices 8 in the wafer 5 of Comparative Example 3 was 621, while in Invention Product 1, Invention Product 2, Invention Product 3, and Invention Product 4, the number of devices 8 in the wafer 5 was 636 and in Invention Product 5, Invention Product 6, Invention Product 7, Invention Product 8, Invention Product 9, the number of devices 8 in the wafer 5 was 626.

Thus, according to Table 1, it was clarified that, in the ingot processing method, the wafer processing method, and the wafer 5 according to the first embodiment, a larger number of devices 8 can be formed while preventing the breakage of the wafer 5 being carried, by forming the linear flat mirror surface portion 6.

According to the present invention, a larger number of devices can be formed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wafer processing method for a wafer formed of a semiconductor material, the wafer processing method comprising:
preparing a wafer that includes a front surface, a back surface on a rear surface of the front surface, and a side surface ranging from the front surface to the back surface and includes a flat mirror surface portion indicating a crystal orientation of the wafer on the side surface; and
grinding the back surface of the wafer prepared in the preparing to form a recess and form a projection surrounding the recess.

2. The wafer processing method according to claim 1, wherein, the grinding includes grinding the wafer without disposing a hard plate on the front surface of the wafer.

3. The wafer processing method according to claim 1, further comprising:
detecting the flat mirror surface portion before or after the grinding; and
storing the wafer in a wafer cassette after the detecting and the grinding, wherein
the storing includes storing the wafer in the wafer cassette while the flat mirror surface portion is positioned in a predetermined orientation with respect to the wafer cassette.

4. An ingot processing method for an ingot formed of a semiconductor material, the ingot processing method comprising:
detecting a crystal orientation of the ingot;
forming a linear flat mirror surface portion along an extending direction of the ingot based on the crystal orientation detected in the detecting;
separating a part of the ingot to form a wafer after the forming; and
grinding a back surface of the wafer to form a recess and form a projection surrounding the recess.

5. A wafer that includes a front surface, a back surface on a rear surface of the front surface, and a side surface ranging from the front surface to the back surface and includes a flat mirror surface portion indicating a crystal orientation of the wafer.

6. The wafer according to claim 5, wherein a width of the flat mirror surface portion is 0.05 mm or more and 34.5 mm or less.

7. The wafer according to claim 5, wherein the side surface is formed in a straight line in a vertical section of the wafer, a front-surface side chamfered portion is formed at a corner between the front surface and the side surface, and a back-surface side chamfered portion is formed at a corner between the back surface and the side surface.

8. The wafer according to claim 7, wherein, in the vertical section of the wafer, the front-surface side chamfered portion is formed in an arc shape continuing from the front surface to the side surface, and the back-surface side chamfered portion is formed in an arc shape continuing from the back surface to the side surface.

9. The wafer according to claim 5, wherein a thickness of the wafer is 900 μm or more.

10. The wafer according to claim 5, wherein the flat mirror surface portion is formed in a linear shape in a region of the side surface of the wafer ranging from a front surface side to a back surface side.
